(19) United States
(12) Patent Application Publication
(10) Pub. No.: US 2012/0049361 A1
(43) Pub. Date: Mar. 1, 2012

(54) SEMICONDUCTOR INTEGRATED CIRCUIT

(76) Inventors: Byoung-Kwon PARK, Gyeonggi-do (KR); Jong-Chern Lee, Gyeonggi-do (KR)

(21) Appl. No.: 12/980,828

(22) Filed: Dec. 29, 2010

(30) Foreign Application Priority Data
Aug. 27, 2010 (KR) 10-2010-0083498

(51) Int. Cl. H01L 23/485; H01L 21/50

(52) U.S. Cl. 257/738; 438/109; 257/E23.021; 257/E21.499

(57) ABSTRACT

A semiconductor integrated circuit includes a semiconductor chip including a memory cell array, a plurality of first through-chip vias configured to vertically penetrate through the semiconductor chip and operate as an interface for a signal and a supply voltage, and a semiconductor substrate. The semiconductor substrate includes a peripheral circuit region coupled to the plurality of first through-chip vias and configured to control the semiconductor chip and a conductivity pattern region configured to operate as an interface for the signal and the supply voltage between the peripheral circuit region and an external controller.

### CROSS-REFERENCE TO RELATED APPLICATIONS

The present application claims priority of Korean Patent Application No. 10-2010-0083498 filed on Aug. 27, 2010, which is incorporated herein by reference in its entirety.

### BACKGROUND OF THE INVENTION

Exemplary embodiments of the present invention relate to a semiconductor designing technology, and more particularly, to a semiconductor integrated circuit (IC) having a three-dimensional (3D) stack package.

Packaging technology for a semiconductor integrated circuit (IC) has made progress in miniaturizing semiconductor IC and obtaining mount reliability. For example, to obtain adequate performance despite miniaturization of electrical/electronic devices, stack packaging has been developed. As the miniaturization and high performance of electric/electronic products are desired, various techniques for a stack package have been disclosed in the art.

The term “stack” in the semiconductor industry refers to a vertically stacked pile of two or more chips or packages. By using a stack package, in case of a memory device for example, a memory device may have a memory capacity two or more times greater than that obtainable through traditional semiconductor integration processes. Also, the stack package provides not only an increase in memory capacity but also an increase in a mounting density and mounting area utilization efficiency.

A stack package may be fabricated through a method of stacking individual semiconductor chips and then packaging the stacked semiconductor chips at one step or a method of stacking previously-packaged individual semiconductor chips. The individual semiconductor chips of the stack package may be electrically coupled to each other through a metal wire or a through-chip via. Here, a stack package using a through-chip via has a structure where the through-chip via is formed within semiconductor chips and the semiconductor chips are physically and electrically coupled to each other vertically through the through-chip via. Here, the through-chip via may be a through-silicon via (TSV).

FIG. 1 illustrates a conventional semiconductor chip for a stack package.

Referring to FIG. 1, a semiconductor chip C for the stack package is formed through forming a via in a semiconductor chip A and forming a through-chip via B by filling the via with a metal having a great conductivity, e.g., copper (Cu). A semiconductor integrated circuit (IC) is fabricated by stacking a plurality of the semiconductor chips C and mounting the stacked plurality of the semiconductor chips C over a printed circuit board (PCB). The fabricated semiconductor integrated circuit (IC) may be referred to as a three-dimensional (3D) stack package semiconductor integrated circuit (IC).

FIG. 2 is a cross-sectional view illustrating the three-dimensional (3D) stack package semiconductor integrated circuit (IC).

In this description, the three-dimensional (3D) stack package semiconductor integrated circuit (IC) is described by taking an example of a semiconductor integrated circuit (IC) including one master chip and four slave chips.

Referring to FIG. 2, the conventional three dimensional (3D) stack package semiconductor integrated circuit (IC) 100 is shown. The semiconductor integrated circuit (IC) 100 includes a package substrate 110 coupled to an external controller 300, a master chip 120 stacked over an upper side of the package substrate 110, a second through-chip via 130 vertically penetrating the master chip 120, first to fourth slave chips 140a, 140b, 140c and 140d vertically stacked on the upper side of the master chip 120, and a plurality of first through-chip vias 150a, 150b, 150c and 150d vertically penetrating the first to the fourth slave chips 140a, 140b, 140c and 140d.

The package substrate 110 electrically couples the master chip 120 to the external controller 300. Metal lines coupled to the second through-chip via 130 are formed on an upper side of the package substrate 110. Solder balls 112 coupled to the external controller 300 are formed on a bottom of the package substrate 110. The metal lines and the solder balls 112 are coupled to each other through respective routes.

The package substrate 110 interface with the external controller 300 through the solder balls 112 to transfer various signals and a supply voltage to the master chip 120. On the other hand, the package substrate 110 transfers the various signals and supply voltage from the master chip 120 to the external controller 300 through the solder balls 112. Here, the package substrate 110 may be a printed circuit board (PCB) made of polymer.

The master chip 120 controls the first to fourth slave chips 140a, 140b, 140c, 140d through the plurality of the first through-chip vias 150a, 150b, 150c and 150d in response to the applied signals and the supply voltage through the package substrate 110 from the external controller 300. The master chip 120 includes a peripheral circuit region (not shown) for controlling the first to the fourth slave chips 140a, 140b, 140c, and 140d.

Here, the peripheral circuit region of the master chip 120 includes input/output buffers for inputting/outputting various signals, data input/output circuits for inputting/outputting data, and a state machine for inputting/outputting addresses and commands excluding a memory cell array region for storing the data.

The first to fourth slave chips 140a, 140b, 140c and 140d include the above-discussed memory cell array region for storing the data or providing the stored data in response to controlling of the master chip 120. The memory cell array region includes a memory cell array and a minimal circuit for storing data or providing the stored data.

The second through-chip via 130 and the plurality of the first through-chip vias 150a, 150b, 150c and 150d are through-silicon vias (TSVs) for interfacing signals and the supply voltage.

The conventional semiconductor integrated circuit (IC) 100 has the following features.

Production cost may increase in separately performing a step of the master chip 120 on the substrate 120 from a step of stacking the first to the fourth slave chip 140a, 140b, 140c, 140d over the master chip 120 at one time or sequentially.

Furthermore, since the peripheral circuit region included in the master chip 120 is disposed in areas where the solder ball 112 and the metal line are not formed, the master chip 120 may experience deterioration in signal integrity (SI).

In addition, the package substrate 110, the master chip 120 and the first to fourth slave chips 140a, 140b, 140c, and 140d may each require a separate equipment for fabrication. Production costs and time may increase due to resetting of equipment in changing chip arrangements and printed circuit board designs.

### SUMMARY OF THE INVENTION

An embodiment of the present invention is directed to a semiconductor integrated circuit (IC) for minimizing the number of through-chip vias for improvement in terms of signal integrity (SI) and reducing the production cost and production time.

In accordance with an embodiment of the present invention, a semiconductor integrated circuit (IC), which includes: a semiconductor chip including a memory cell array; a plurality of first through-chip vias configured to vertically penetrate through the semiconductor chip and operate as an interface for a signal and a supply voltage; and a semiconductor substrate including a peripheral circuit region coupled to the plurality of first through-chip vias and configured to control the semiconductor chip, and a conductivity pattern region configured to operate as an interface for the signal and the supply voltage between the peripheral circuit region and an external controller.

In accordance with another embodiment of the present invention, a semiconductor integrated circuit (IC), which includes: stacking a semiconductor chip including a memory cell array on a semiconductor substrate; and forming a peripheral circuit region arranged to be coupled to a plurality of first through-chip vias and a conductivity pattern region configured to operate as an interface for a signal and a supply voltage between the peripheral circuit region and an external controller, wherein the first through-chip vias are coupled between the semiconductor chip and the peripheral circuit region and portions of the peripheral circuit region and the conductivity pattern region are formed simultaneously.

### BRIEF DESCRIPTION OF THE DRAWINGS

FIG. 1 illustrates a conventional semiconductor chip for a stack package.

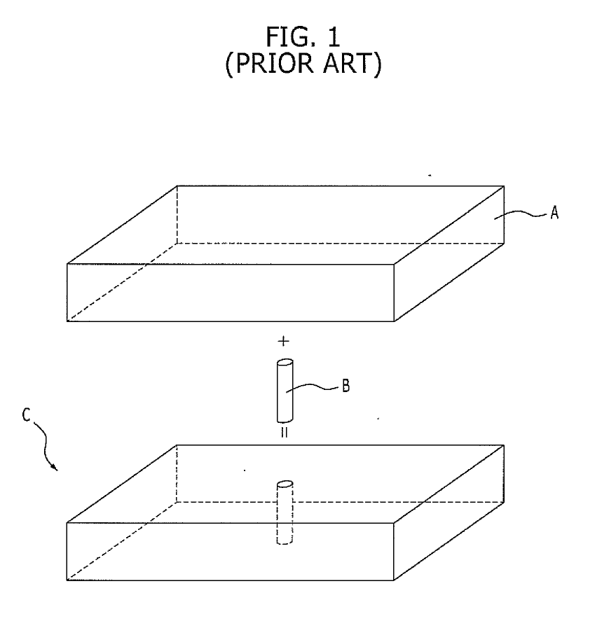

FIG. 2 is a cross-sectional view illustrating a conventional semiconductor integrated circuit (IC) having three dimensional (3D) stack package.

FIG. 3 is a cross-sectional view illustrating semiconductor integrated circuit (IC) having a three dimensional (3D) stack package in accordance with an embodiment of the present invention.

FIG. 4 is a plan view illustrating a package substrate in FIG. 3.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

In this description, the present invention is described by taking an example of a package including a semiconductor substrate and four through-chip vias.

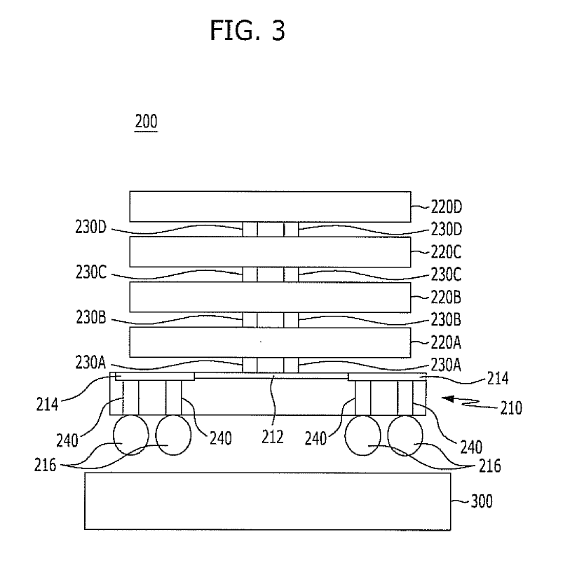

FIG. 3 is a cross-sectional view illustrating a semiconductor integrated circuit (IC) having a three dimensional (3D) stack package in accordance with an embodiment of the present invention.

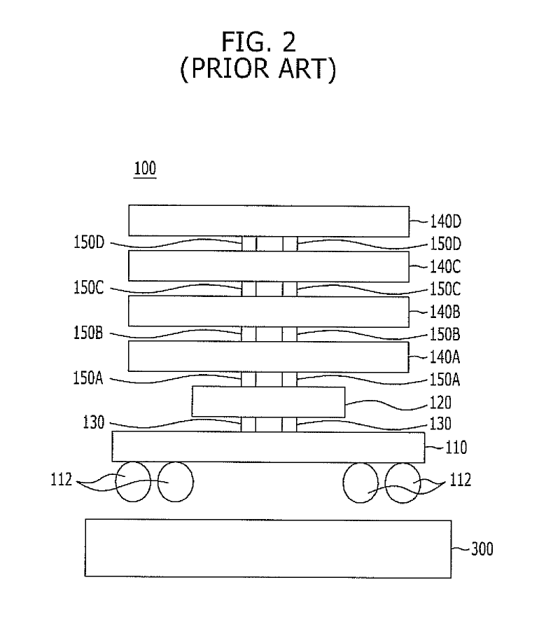

The cross-sectional view of semiconductor chips and through-chip vias are shown in FIG. 3, where each chip or via is substantially the same as the corresponding element in FIG. 2.

Referring to FIG. 3, the semiconductor integrated circuit (IC) 200 includes a semiconductor substrate 210 for interfacing various signals and a supply voltage with an external controller 300, first to fourth semiconductor chips 220A, 220B, 220C and 220D vertically stacked over an upper side of the semiconductor substrate 210 and first through-chip vias 230A, 230B, 230C and 230D vertically penetrated into the first to fourth semiconductor chips 220A, 220B, 220C and 220D. The first through-chip vias include through-silicon vias (TSV).

The semiconductor substrate 210 includes a peripheral circuit region 212 and a conductivity pattern region 214 formed on an upper side of the semiconductor substrate 210. The semiconductor substrate 210 includes external connection terminal 216 formed on bottom side of the semiconductor substrate 210. The external connection terminal 216 includes solder balls.

The semiconductor substrate 210 includes a plurality of second through-chip vias 240 vertically penetrating through the semiconductor substrate 210 and electrically coupling the conductivity pattern region 214 with the external connection terminal 216. The plurality of second through-chip vias 240 include through-silicon vias (TSV).

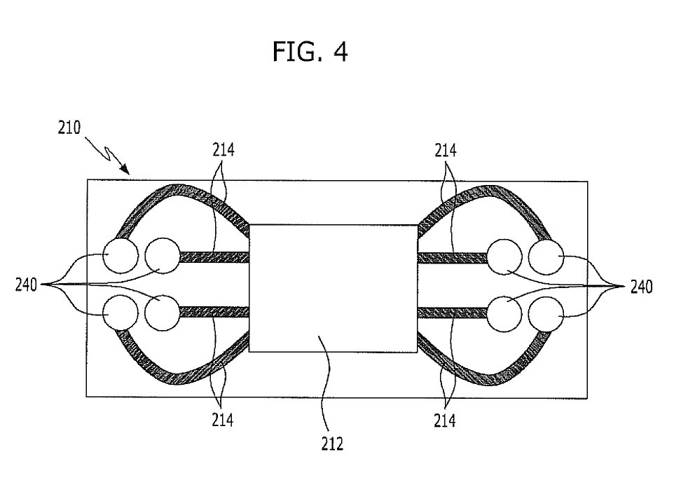

FIG. 4 is a plan view illustrating a semiconductor substrate in FIG. 3.

Referring to the FIGS. 3 and 4, the peripheral circuit region 212 are coupled to the plurality of the first through-chip vias 230A, 230B, 230C and 230D and control the first to fourth semiconductor chips 220A, 220B, 220C and 220D through the plurality of the first through-chip vias 230A, 230B, 230C and 230D.

While not shown in the drawings, the peripheral circuit region 212 includes various input/output buffers, data input/output circuits for inputting/outputting data, and a state machine for inputting/outputting addresses and commands. The conductivity pattern region 214 includes a plurality of metal lines for electrically coupling the peripheral circuit region 212 to the plurality of the second through-chip vias 240. The plurality of metal lines may each be a metal such as copper (Cu) having a great electric conductivity.

The semiconductor substrate 210 may be a silicon substrate for integrating the peripheral circuit region 212 and the conductivity pattern region 214 in a substrate.

Meanwhile, the second through-chip vias 240 may be a metal such as copper (Cu) having a great electric conductivity like the conductivity pattern region 214. The plurality of the second through-chip vias 240 may be through-silicon vias (TSV).

While not shown in the drawings, the first to fourth semiconductor chips 220A, 2208, 220C and 220D include a memory cell array region, store data in the memory cell array region and provide the data to the memory cell array region in response to outputs of the peripheral circuit region 212. The memory cell array region may include minimal circuits for storing and providing the data, e.g., a decoder for decoding the address and a memory cell array.

The plurality of the first through-chip vias 230A, 230B, 230C and 230D interface signals and the supply voltage between the peripheral circuit region 212 and the first to fourth semiconductor chips 220A, 220B, 220C and 220D.

The plurality of the first through-chip vias 230A, 230B, 230C and 230D each be formed of a metal such as copper (Cu) and through-silicon vias TSV having a great electric conductivity.

While not shown in the drawings, the plurality of the first through-chip vias 230A, 230B, 230C and 230D are each coupled to a corresponding one of semiconductor chip 220A, 220B and 220C and the semiconductor substrate 210 through a bump pad.

In accordance with the embodiment of the present invention, the semiconductor integrated circuit (IC) 200 includes the peripheral circuit region 212 for controlling the first to fourth semiconductor chips 220A, 220B, 220C and 220D and includes the conductivity pattern region 214 for electrically coupling the peripheral circuit region 212 with the external controller 300, where the peripheral circuit region 212 and the conductivity pattern region 214 are formed on a single substrate 210. In this manner, production costs and production time are decreased due to decreasing of the number of stacking processes when a stack packaging process is performed. Here since a master slave chip is not stacked on the semiconductor substrate 110, one stage stacking process is used to simplify the manufacturing process and reduce costs, where the semiconductor chips are stacked over the semiconductor substrate 210 in one stage.

Since the peripheral circuit region 210 and the conductivity pattern region 214 are disposed in the semiconductor substrate 210, their arrangement may be determined as appropriate. Accordingly, since the peripheral circuit region 210 and the conductivity pattern region 214 are not separated from each other nor disposed within respective limited spaces, appropriate signal integrity (SI) may be obtained by appropriately disposing the peripheral circuit region 210 and the conductivity pattern region 214 to reduce line loads.

When fabrication of the peripheral circuit region 210 and fabrication of the conductivity pattern region 214 are performed together, same processes such as a fabricating process of the metal line that are performed for both regions are simultaneously performed to reduce production costs and production time by reducing a number of manufacturing processes.

According to an exemplary embodiment of the present invention, the number of through-chip vias for transferring signals enabled at different times according to operation modes may be reduced by using a common through-chip via for transferring the signals. Therefore, the overall area of a semiconductor integrated circuit (IC) may be reduced and net die may be increased.

While the present invention has been described with respect to the specific embodiments, it will be apparent to those skilled in the art that various changes and modifications may be made without departing from the spirit and scope of the invention as defined in the following claims.

While silicon substrate has been illustrated, the present invention is not limited thereto and may be applied in other cases including any reasonably suitable substrate for forming a peripheral circuit region and a conductive pattern region on the same substrate.

According to an exemplary embodiment of the present invention, the semiconductor integrated circuit (IC) has first and second through-chip vias. However, a semiconductor integrated circuit (IC) may include more through-chip vias (for example, in the number of hundreds or thousands).

What is claimed is:

1. A semiconductor integrated circuit, comprising:
a semiconductor chip including a memory cell array;
a plurality of first through-chip vias configured to vertically penetrate through the semiconductor chip and operate as an interface for a signal and a supply voltage; and
a semiconductor substrate including a peripheral circuit region coupled to the plurality of first through-chip vias configured to control the semiconductor chip and a conductivity pattern region configured to operate as an interface for the signal and the supply voltage between the peripheral circuit region and an external controller.

2. The semiconductor integrated circuit of claim 1, further comprising a plurality of external connection terminals configured to be electrically coupled to the external controller.

3. The semiconductor integrated circuit of claim 2, wherein the peripheral circuit region and the conductivity pattern region are formed on a first side of the semiconductor substrate, the plurality of the external connection terminal is formed on an opposite side of the semiconductor substrate.

4. The semiconductor integrated circuit of claim 3, wherein the plurality of external connection terminals are formed on one side of the semiconductor substrate.

5. The semiconductor integrated circuit of claim 4, further comprising a plurality of second through-chip vias that couple the conductivity pattern region to the plurality of the external connection terminal.

6. The semiconductor integrated circuit of claim 5, wherein the plurality of the first and second through-chip vias each include a through-silicon via (TSV).

7. The semiconductor integrated circuit of claim 1, wherein the semiconductor substrate is a silicon substrate.

8. The semiconductor integrated circuit of claim 1, wherein the conductivity pattern region includes a metal line.

9. The semiconductor integrated circuit of claim 1, further comprising:
at least one bump pad configured to electrically connect a corresponding one of the plurality of the first through-chip vias to the peripheral circuit region.

10. The semiconductor integrated circuit of claim 2, wherein the plurality of external connection terminals include solder balls.

11. The semiconductor integrated circuit of claim 1, wherein the conductivity pattern region includes a conductivity pattern that are formed on one side of the semiconductor substrate and connect the peripheral circuit region to a plurality of second through chip vias penetrating through the semiconductor substrate.

12. The semiconductor integrated circuit of claim 11, wherein the second through chip vias are disposed on opposite sides of the peripheral circuit region.

13. A method comprising:
stacking a semiconductor chip including a memory cell array on a semiconductor substrate; and
forming a peripheral circuit region arranged to be coupled to a plurality of first through-chip vias and a conductivity pattern region configured to operate as an interface for a signal and a supply voltage between the peripheral circuit region and an external controller, wherein the first through-chip vias are coupled between the semiconductor chip and the peripheral circuit region and portions of the peripheral circuit region and the conductivity pattern region are formed simultaneously.

14. The method of claim 13, further comprising forming a plurality of second through chip vias penetrating through the semiconductor substrate, wherein the second conductivity pattern region includes a conductivity pattern that is formed on one side of the semiconductor substrate and connects the peripheral circuit region to the plurality of second through chip vias.
